(19) United States
(12) Patent Application Publication
(10) Pub. No.: US 2026/0341343 A1
(43) Pub. Date: Oct. 29, 2026

(54) WRITE ASSIST CIRCUIT FOR GENERATING BITCELL POWER SUPPLY VOLTAGE IN A STATIC RANDOM ACCESS MEMORY

(71) Applicant: SAMSUNG ELECTRONICS CO., LTD., Suwon-si (KR)

(72) Inventors: Gopi Sunanth Kumar Gogineni, Bengaluru (IN); Sarvesh Agarwal, Bengaluru (IN); Lava Kumar Pulluru, Bengaluru (IN); Manish Chandra Joshi, Bengaluru (IN)

(73) Assignee: SAMSUNG ELECTRONICS CO., LTD., Suwon-si (KR)

(21) Appl. No.: 19/644,131

(22) Filed: Apr. 10, 2026

(30) Foreign Application Priority Data
Apr. 26, 2025 (IN) 202541040487
Jan. 13, 2026 (IN) 202541040487

(51) Int. Cl. G11C 11/418; G11C 5/14; G11C 11/419

(52) U.S. Cl. CPC G11C 11/418; G11C 5/14; G11C 11/419

(57) ABSTRACT

A write assist circuit for generating a bitcell power supply voltage in a static random access memory. The write assist circuit performs a pull-down operation on the bitcell power supply voltage. The write assist circuit includes a pull-up circuit controlled by a core power enable signal and a write assist enable signal and prevents a short supply path between a core power supply voltage and a ground. The write assist circuit includes a pass gate coupled to the pull-up circuit and controlled by a logical low voltage or a logical high voltage, and provides a pull-down path for the bitcell power supply voltage. The write assist circuit includes a pull-down circuit, to pull down the bitcell power supply voltage, including an n-type metal-oxide-semiconductor (NMOS) pull-down transistor, a p-type metal-oxide-semiconductor (PMOS) pull-down transistor coupled in parallel with the pull-down transistor, and a footer coupled between the pull-down transistor and the ground.

### CROSS-REFERENCE TO RELATED APPLICATIONS

This application is based on and claims priority under 35 U.S.C. § 119 to Indian Provisional Patent Application No. 202541040487, filed on Apr. 26, 2025, and Indian Complete patent Application No. 202541040487, filed on Jan. 13, 2026, in the Indian Patent Office, the disclosures of which are incorporated by reference herein in their entireties.

### BACKGROUND

### 1. Field

The present disclosure generally relates to the field of semiconductor memory devices, and more particularly, to a write assist circuit for generating a bitcell power supply voltage in a static random access memory (SRAM).

### 2. Description of Related Art

In a static random access memory (SRAM), a write operation is a critical process for ensuring that data is stored correctly. However, as operating voltage (VDD) decreases, a likelihood of write operation failure increases. This is because SRAM cells, which are typically implemented using a six-transistor (6T) design, rely on an interplay between n-channel metal-oxide semiconductor (NMOS) and p-channel metal-oxide semiconductor (PMOS) transistors to store and write the data. When the operating voltage becomes too low, the ability of the transistors to switch on or off becomes impaired, leading to a failure in writing an intended value. As a result, a minimum voltage (Vₘᵢₙ) at which the SRAM can operate reliably is also constrained by the ability of the SRAM cell to successfully write new data. In addition to low voltages, the write operation in the SRAM is also significantly influenced by a process corner (for example, a fast NMOS-fast PMOS (FF) corner, a slow NMOS-slow PMOS (SS) corner, a fast NMOS-slow PMOS (FS) corner, and a slow NMOS-fast PMOS (SF) corner) in which the transistors are fabricated, as process variations affect characteristics (such as threshold voltage, mobility, and the drive strength) of the transistors. In other words, the performance of SRAM write operations varies across different process corners.

FIG. 1A illustrates a circuit diagram of a 6T SRAM bitcell 100, in accordance with the related art. The bitcell 100 comprises six transistors (M1-M6) and is designed to store a single bit of data at nodes Q and Q_{b}. If the node Q is high (logic “1”), the node Q_{b} will be low (logic “0”), and vice versa. The transistors M3 and M6 are access transistors controlled by a wordline (WL), responsible for controlling access to the stored data during read and write operations. The transistors M3 and M6 are also connected to bitlines BL and BLB respectively. The transistors M1 and M5 are pull-up transistors, connected to the positive supply voltage (VDD). The transistors M2 and M4 are pull-down transistors, connected to ground (GND).

Before the write operation, the bitlines BL and BLB are precharged to ‘1’, thereby ensuring that the bitlines BL and BLB are at same voltage level. During the write operation, based on an external data input (DI), one of the bitlines BL and BLB is pulled to the GND (i.e., logic ‘0’), while keeping the other bitline at the VDD (i.e., logic ‘1’). Further, the wordline (WL) is asserted (i.e., set to logic ‘1’), thereby turning on the access transistors M3 and M6. This allows the data on the bitlines BL and BLB to be transferred to the nodes Q and Q_{b} of the bitcell 100.

In latest applications such as Artificial Intelligence (AI) and Machine Learning (ML), low voltage operation is critical for achieving low power consumption. As a result, reducing the minimum operating voltage (Vₘᵢₙ) of the SRAM bitcell is crucial for supporting energy-efficient designs. However, the Vₘᵢₙ of the SRAM bitcell is limited by the write operation.

Table 1, as provided below, shows a Write Margin (WRM) (hereinafter “write sigma”) for the SRAM bitcell 100, indicating ability of the bitcell 100 to successfully perform the write operation at various supply voltages. The table is provided for a specific process and temperature condition, denoted as SF/−40 °C (i.e., for the SF process corner and a temperature of −40 °C).

TABLE 1
WRM at different voltages
Process: SF; Temperature: −40 °C

| | VDD (V) | | | | | | | | | | | |
|---|---|---|---|---|---|---|---|---|---|---|---|---|
| | 0.55 | 0.6 | 0.65 | 0.7 | 0.75 | 0.8 | 0.85 | 0.9 | 0.95 | 1 | 1.05 | 1.1 |
| WRM | 3.56 | 4.35 | 5.08 | 5.76 | 6.40 | 6.98 | 7.57 | 8.06 | 8.55 | 8.98 | 9.42 | 9.86 |

As shown in the Table 1, at lower voltages such as when VDD is less than 0.7V (e.g., for VDD=0.55V, 0.6V, or 0.65V), the WRM values are lower suggesting that the bitcell may fail to write reliably at lower voltages.

Further, the WRM and the ability of the SRAM bitcell to perform write operations also vary across different process corners: SF (Slow-Fast), FF (Fast-Fast), FS (Fast-Slow), and SS (Slow-Slow). Among these process corners, the SF process corner tends to be the weakest for write operations, primarily due to the interaction between the access transistor and the pull-up transistor. Table 2 provided below shows the WRM of the SRAM bitcell in different process corners. The table is provided for a specific VDD (0.6V) and temperature condition (−40 °C). As shown in Table 2, the WRM is lowest for the SF corner.

TABLE 2
WRM with process variation
Voltage: 0.6 V; Temperature: −40 °C

| Process | SF | FS | FF | SS |
|---|---|---|---|---|
| WRM | 4.35 | 7.81 | 6.69 | 5.37 |

FIG. 1B illustrates a signal flow diagram depicting waveforms during the write operation in the SRAM bitcell 100 of FIG. 1A, in accordance with the related art. As shown in the FIG. 1B, when the WL rises by 50% and the BL falls by 50%, the write operation begins. And by the time, the WL falls by 50% or the BL rises by 50%, or whichever is earlier, the write operation should be completed. Thus, a window between nodes 112 and 114 in the figure in which the SRAM bitcell can latch incoming data is WRITE_WINDOW (EWW). The EWW may be calculated as difference between minimum time at which the WL falls to 50% and the BL rises to 50%, and maximum time at which the WL rises to 50% and the BL falls to 50%, as shown in equation (1) provided below.

WRITE_WINDOW (EWW)=MIN(WL fall 50%,BL rise 50%)−MAX(WL rise 50%,BL_FALL 50%) (1)

Further, a time taken by the SRAM bitcell to actually store the data after the write operation begins is referred to as a WRITE_TIME (EWT). The EWT may be calculated by the difference between one of a maximum time at which the node Q falls to 30% or the node Q_{b} rises to 70% during a write-0 operation or a maximum time at which the node Q rises to 70% or the node Q_{b} falls to 30% during a write-1 operation, and time when the WL rises to 50% and the BL falls to 50%, as shown in equation (2) provided below.

WRITE_TIME (EWT)=MAX(Q fall 30%,Q_{b} rise 70%) or MAX(Qrise70%,Q_{b}fall30%)−MAX(WL rise 50%,BL_FALL 50%) (2)

Furthermore, a WRITE_MARGIN (WM), which is a ratio of the WRITE_WINDOW to the WRITE_TIME (as shown in equation (3) below), indicates robustness of the write operation. A higher WM indicates better robustness in the write operation, whereas a lower WM can result in unreliable writes, especially at reduced supply voltages.

WRITE MARGIN=WRITE_WINDOW/WRITE_TIME (3)

Table 3 provided below shows the WM at a macro level for an SRAM instance 8192×32m4b8, across the different process corners. Here, the expression “SRAM instance 8192×32m4b8” denotes the configuration parameters of the static random-access memory (SRAM) macro. Specifically, the first number “8192” indicates that the memory array includes 8,192 addressable words (rows). The next number “32” indicates that each word stores 32 bits of data. The suffix “m4” represents the number of banks or memory partitions included in the SRAM macro. The suffix “b8” represents the byte-enable width of the SRAM instance. Table 3 emphasizes the challenge of maintaining reliable write operations at lower voltages, particularly in the SF process corner. In Table 3, PVT refers to process, voltage and temperature.

TABLE 3
Write Margin Data for 8192x32m4b8 Instance

| PVT | EWW (ps) | EWT (ps) | WM |
|---|---|---|---|
| SF/RCMAX/0.595 V/150 c | 633 | 579 | 1.09 |
| FF/RCMAX/0.595 V/150 c | 519 | 222 | 2.34 |
| FS/RCMAX/0.595 V/150 c | 641 | 164 | 3.92 |
| SS/RCMAX/0.595 V/150 c | 796 | 318 | 2.50 |

To address the above-mentioned issues, the SRAM designs typically employ write assist circuits that either boost or reduce drive strength of bitcell transistors to help with the write operations. One such write assist circuit is a bitcell power supply voltage (VDDA) lowering write assist circuit, which reduces the drive strength of the pull-up transistors M1 and M5 by reducing the bitcell power supply voltage VDDA. However, the VDDA lowering write assist circuit provides less assist level in the SF process corner as compared to the other corners.

Therefore, there exists a need to develop techniques for providing more assist level in the SF process corner and reducing the Vₘᵢₙ of the SRAM.

### SUMMARY

This summary is provided to introduce a selection of concepts, in a simplified format, that are further described in the detailed description. This summary is neither intended to identify key or essential concepts of the disclosure and nor is it intended for determining the scope of the disclosure.

According to an aspect of the disclosure, there is provided a write assist circuit for generating a bitcell power supply voltage in a static random access memory (SRAM), wherein the write assist circuit is configured to perform a pull-down operation on the bitcell power supply voltage, the write assist circuit including: a pull-up circuit coupled to a bitcell power supply node, wherein the pull-up circuit is configured to be controlled by a core power enable signal and a write assist enable signal, and to prevent a short supply path between a core power supply voltage and a ground during the pull-down operation; a pass gate coupled to the pull-up circuit through the bitcell power supply node, wherein the pass gate is configured to be controlled by one of a logical low voltage and a logical high voltage, and to provide a pull-down path for the bitcell power supply voltage; and a pull-down circuit configured to pull down the bitcell power supply voltage during a write operation, the pull-down circuit including: an n-type metal-oxide-semiconductor (NMOS) pull-down transistor, a p-type metal-oxide-semiconductor (PMOS) pull-down transistor coupled in parallel with the NMOS pull-down transistor, and a footer coupled between the NMOS pull-down transistor and the ground.

According to an aspect of the disclosure, there is provided a method of controlling a write assist circuit for generating a bitcell power supply voltage in a static random access memory (SRAM), the write assist circuit including a pull-up circuit coupled to a bitcell power supply node, controlled by a core power enable signal and a write assist enable signal, and configured to prevent a short supply path between a core power supply voltage and a ground during a pull-down operation, a pass gate coupled to the pull-up circuit through the bitcell power supply node, controlled by one of a logical low voltage and a logical high voltage, and configured to provide a pull-down path for the bitcell power supply voltage, and a pull-down circuit configured to pull down the bitcell power supply voltage during a write operation, the pull-down circuit including an n-type metal-oxide-semiconductor (NMOS) pull-down transistor, a p-type metal-oxide-semiconductor (PMOS) pull-down transistor coupled in parallel with the NMOS pull-down transistor, and a footer coupled between the NMOS pull-down transistor and the ground, the method including: applying the core power supply voltage to the write assist circuit; and performing, via the write assist circuit, the pull-down operation on the bitcell power supply voltage.

To further clarify the advantages and features of the present disclosure, a more particular description will be rendered by reference to specific embodiments thereof, which is illustrated in the appended drawings. It is appreciated that these drawings depict only example embodiments and are therefore not to be considered limiting of the scope the disclosure. Embodiments will be described and explained with additional specificity and detail with the accompanying drawings.

### BRIEF DESCRIPTION OF THE DRAWINGS

These and other features, aspects, and advantages of certain embodiments will become better understood when the following detailed description is read with reference to the accompanying drawings in which like characters represent like parts throughout the drawings, in which:

FIG. 1A illustrates a circuit diagram of a six-transistor (6T) static random access memory (SRAM) bitcell, in accordance with the related art;

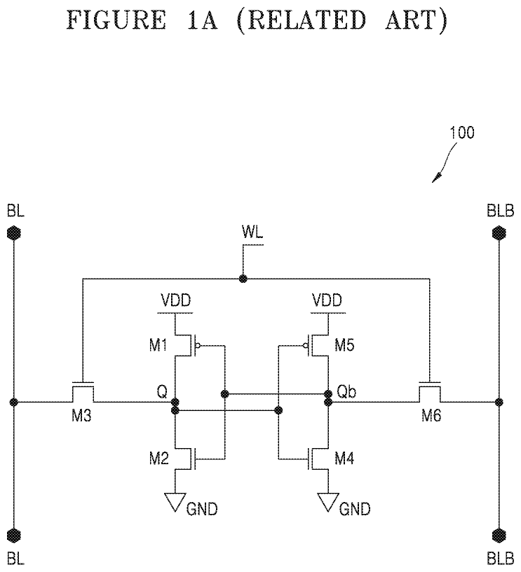

FIG. 1B illustrates a signal flow diagram depicting waveforms during a write operation in the 6T SRAM bitcell of FIG. 1A, in accordance with the related art;

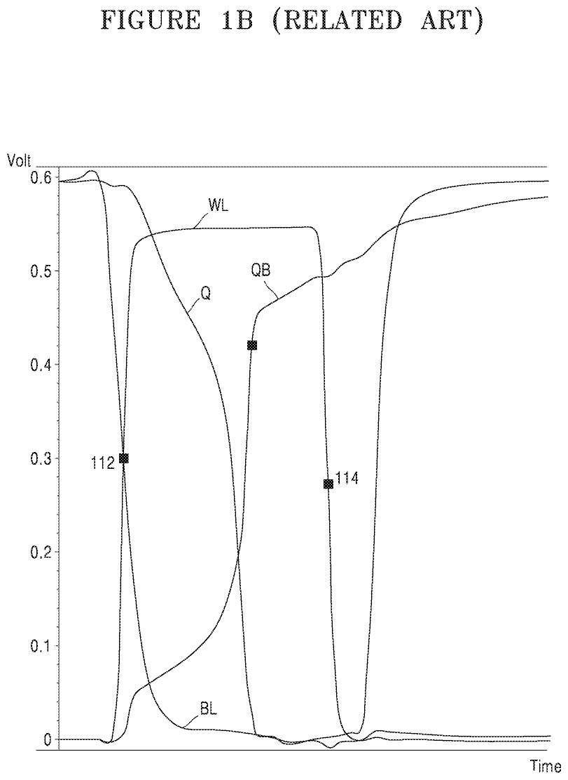

FIG. 2A illustrates a schematic architecture of a write assist circuit for generating the bitcell power supply voltage in the SRAM, according to a first embodiment of the present disclosure;

FIG. 2B illustrates a circuit diagram of the write assist circuit of FIG. 2A, according to the first embodiment of the present disclosure

FIG. 3A illustrates a schematic architecture of the write assist circuit for generating the bitcell power supply voltage in the SRAM, according to a second embodiment of the present disclosure;

FIG. 3B illustrates a circuit diagram of the write assist circuit of FIG. 3A, according to the second embodiment of the present disclosure;

FIG. 4A illustrates a schematic architecture of the write assist circuit for generating the bitcell power supply voltage in the SRAM, according to a third embodiment of the present disclosure;

FIG. 4B illustrates a circuit diagram of the write assist circuit of FIG. 4A, according to the third embodiment of the present disclosure;

FIG. 5A illustrates a schematic architecture of the write assist circuit for generating the bitcell power supply voltage in the SRAM, according to a fourth embodiment of the present disclosure;

FIG. 5B illustrates a circuit diagram of the write assist circuit of FIG. 5A, according to the fourth embodiment of the present disclosure;

FIG. 6A illustrates a schematic architecture of the write assist circuit for generating the bitcell power supply voltage in the SRAM, according to a fifth embodiment of the present disclosure;

FIG. 6B illustrates a circuit diagram of the write assist circuit of FIG. 6A, according to the fifth embodiment of the present disclosure;

FIG. 7 illustrates a computing system, in accordance with one or more embodiments; and

FIG. 8 illustrates a flow chart of a method for generating the bitcell power supply voltage VDDA in the SRAM, in accordance with one or more embodiments.

Further, skilled artisans will appreciate that elements in the drawings are illustrated for simplicity and may not have necessarily been drawn to scale. For example, the flow charts illustrate the method in terms of the most prominent steps involved to help to improve understanding of aspects of the present disclosure. Furthermore, in terms of the construction of the system, one or more components of the system may have been represented in the drawings by conventional symbols, and the drawings may show only those specific details that are pertinent to understanding the embodiments so as not to obscure the drawings with details that will be readily apparent to those of ordinary skill in the art having the benefit of the description herein.

### DETAILED DESCRIPTION

Reference will now be made to example embodiments illustrated in the drawings and specific language will be used to describe the same. It will nevertheless be understood that no limitation of the scope the present disclosure is thereby intended, such alterations and further modifications in the illustrated system, and such further applications of the principles of the present disclosure as illustrated therein being contemplated as would normally occur to one skilled in the art.

It will be understood by those skilled in the art that the foregoing general description and the following detailed description are explanatory and are not intended to be restrictive.

Reference throughout this specification to “an aspect”, “another aspect” or similar language means that a particular feature, structure, or characteristic described in connection with the embodiment is included in at least one embodiment. Thus, appearances of the phrase “in an embodiment”, “in another embodiment” and similar language throughout this specification may, but do not necessarily, all refer to the same embodiment.

The terms “comprises”, “comprising”, or any other variations thereof, are intended to cover a non-exclusive inclusion, such that a process or method that comprises a list of steps does not include only those steps but may include other steps not expressly listed or inherent to such process or method. Similarly, one or more systems or sub-systems or elements or structures or components proceeded by “comprises . . . a” does not, without more constraints, preclude the existence of other devices or other sub-systems or other elements or other structures or other components or additional devices or additional sub-systems or additional elements or additional structures or additional components.

The embodiments herein and the various features and advantageous details thereof are explained more fully with reference to the non-limiting embodiments that are illustrated in the accompanying drawings and detailed in the following description. Descriptions of well-known components and processing techniques are omitted so as to not unnecessarily obscure the embodiments herein. Also, the various embodiments described herein are not necessarily mutually exclusive, as some embodiments can be combined with one or more other embodiments to form new embodiments. The term “or” as used herein, refers to a non-exclusive or unless otherwise indicated. The examples used herein are intended merely to facilitate an understanding of ways in which the embodiments herein can be practiced and to further enable those skilled in the art to practice the embodiments herein. Accordingly, the examples should not be construed as limiting the scope of the embodiments herein.

As is traditional in the field, embodiments may be described and illustrated in terms of blocks that carry out a described function or functions. These blocks, which may be referred to herein as units or modules or the like, are physically implemented by analog or digital circuits such as logic gates, integrated circuits, microprocessors, microcontrollers, memory circuits, passive electronic components, active electronic components, optical components, hardwired circuits, or the like, and may optionally be driven by firmware and software. The circuits may, for example, be embodied in one or more semiconductor chips, or on substrate supports such as printed circuit boards and the like. The circuits constituting a block may be implemented by dedicated hardware, or by a processor (e.g., one or more programmed microprocessors and associated circuitry), or by a combination of dedicated hardware to perform some functions of the block and a processor to perform other functions of the block. Each block of the embodiments may be physically separated into two or more interacting and discrete blocks without departing from the scope of the present disclosure. Likewise, the blocks of the embodiments may be physically combined into more complex blocks without departing from the scope of the present disclosure.

The accompanying drawings are used to help easily understand various technical features and it should be understood that the embodiments presented herein are not limited by the accompanying drawings. As such, the present disclosure should be construed to extend to any alterations, equivalents, and substitutes in addition to those which are particularly set out in the accompanying drawings. Although the terms first, second, etc. may be used herein to describe various elements, these elements should not be limited by these terms. These terms are generally only used to distinguish one element from another.

The present disclosure discloses a write assist circuit for generating a bitcell power supply voltage (VDDA) in a static random access memory (SRAM). Particularly, the present disclosure discloses the write assist circuit for performing a pull-down operation on the bitcell power supply voltage VDDA. The generated VDDA helps in improving a write operation in the SRAM.

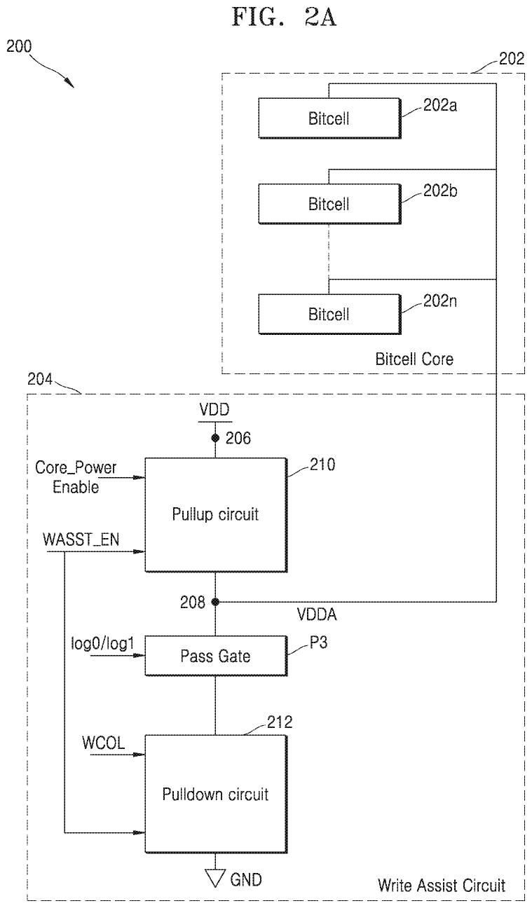

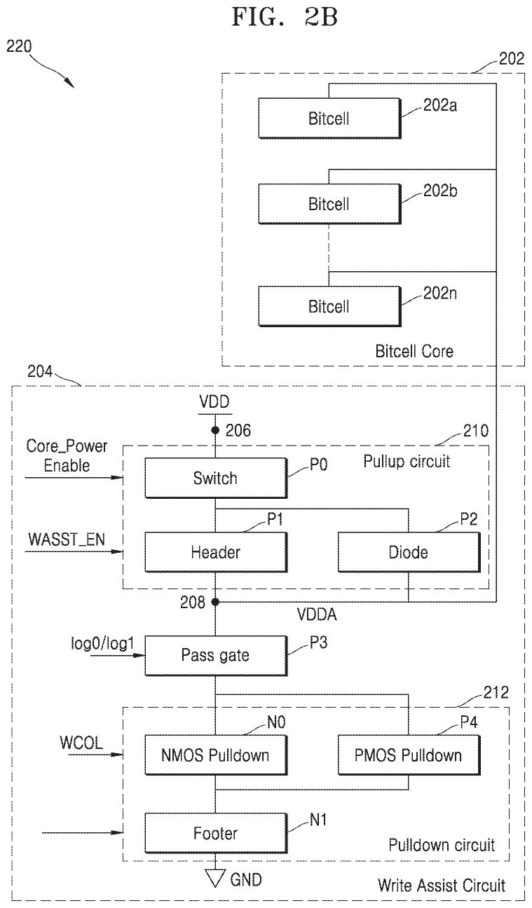

FIG. 2A illustrates a schematic architecture 200 of the write assist circuit 204 for generating the bitcell power supply voltage (i.e., the bitcell power supply voltage VDDA) in the SRAM, according to a first embodiment of the present disclosure. In one embodiment, the generated bitcell power supply voltage VDDA may be supplied to a bitcell core 202. Particularly, the generated bitcell power supply voltage VDDA may be supplied to a plurality of bitcells 202a, 202b, . . . 202n in the bitcell core 202 ensuring a reliable write operation. In one embodiment, the bitcell 202a, 202b, . . . , 202n may refer to smallest unit of storage in the SRAM that holds a single bit of data.

In an embodiment, the write assist circuit 204 may include a pull-up circuit 210, a pass gate (P3), and a pull-down circuit 212.

In an embodiment, the pull-up circuit 210 may be connected to a bitcell power supply node 208 (also referred to as an output node). Particularly, the pull-up circuit 210 may be connected between the bitcell power supply node 208 and a core power supply node 206 (also referred to as an power supply node). The pull-up circuit 210 may be controlled by a core power enable (Core_Power Enable) signal and a write assist enable (WASST_EN) signal. The Core_Power Enable signal may refer to a control signal used to manage power supply to the bitcell core 202 in different modes of operation (such as a normal mode, a retention mode, and a power-down mode). Further, the WASST_EN signal may refer to a control signal used in the SRAM to enable or disable the write assist circuit 204 during the write operation. A pulse width of the WASST_EN signal may be based on a plurality of external input pins. Further, a magnitude of pull-down of the bitcell power supply voltage VDDA may be based on the pulse width of the WASST_EN signal. The pull-up circuit 210 may be configured to prevent a short supply path between the core power supply voltage (VDD) and a ground (GND) during the pull-down operation. The components of the pull-up circuit 210 are explained in detail in conjunction with FIG. 2A in the forthcoming paragraphs.

In an embodiment, the P3 may be coupled to the pull-up circuit 210 through the bitcell power supply node 208. The P3 may be controlled by one of a logical low voltage (log 0) and a logical high voltage (log 1). Further, the P3 may provide a pull-down path for the bitcell power supply voltage VDDA. Furthermore, the P3 may also prevent excessive dropping of the bitcell power supply voltage VDDA. The P3 may be one of a p-channel metal-oxide semiconductor (PMOS) gate and an n-channel metal-oxide semiconductor (NMOS) gate.

In an embodiment, the pull-down circuit 212 may be configured to pull down the bitcell power supply voltage VDDA during the write operation. The pull-down circuit 212 may be coupled between the P3 and the GND. The components of the pull-down circuit 212 are explained in detail in conjunction with FIG. 2A in the forthcoming paragraphs.

FIG. 2B illustrates a circuit diagram 220 of the write assist circuit 204 of FIG. 2A, according to the first embodiment of the present disclosure.

As shown in FIG. 2B, the pull-up circuit 210 may include a switch (P0), a header (P1), and a diode (P2).

In an embodiment, the P0 may be coupled to the core power supply voltage node 206. Further, the P0 may be controlled by the Core_Power Enable signal. The P0 may be one of a PMOS switch and an NMOS switch.

In an embodiment, the P1 may be coupled between the P0 and the P3. The P1 may be controlled by one of the WASST_EN signal and a complementary WASST_EN (cWASST_EN). Further, the P1 may be configured to prevent the short supply path between the core power supply voltage VDD and the GND during the pull-down operation. The P1 may be one of a PMOS header and an NMOS header.

In an embodiment, the diode may be coupled parallelly with the P1. The diode may be configured to prevent an excessive pull-down of the bitcell power supply voltage VDDA. Further, the diode may be one of a PMOS diode and an NMOS diode.

In an embodiment, the pull-down circuit 212 may include an NMOS pull-down transistor (N0), a PMOS pull-down transistor (P4), and a footer (N1).

In an embodiment, the P4 may be coupled in a parallel fashion with the N0. Advantageously, the P4 enables a uniform pull-down of the bitcell power supply voltage VDDA across a plurality of process corners of the SRAM. The plurality of process corners may include a fast NMOS-fast PMOS (FF) process corner, a slow NMOS-fast PMOS (SF) process corner, a fast NMOS-slow PMOS (FS) process corner, and a slow NMOS-slow PMOS (SS) process corner. Particularly, the P4 coupled in a parallel fashion with the N0 enables an optimized pull-down of the bitcell power supply voltage VDDA for the SF process corner.

In an embodiment, the N1 may be coupled between the N0 and the GND. The N1 may be one of a PMOS footer and an NMOS footer. A footer circuit may be used to separate a virtual ground from a ground. Similarly, a header circuit may be used to separate a virtual VDD from a power supply.

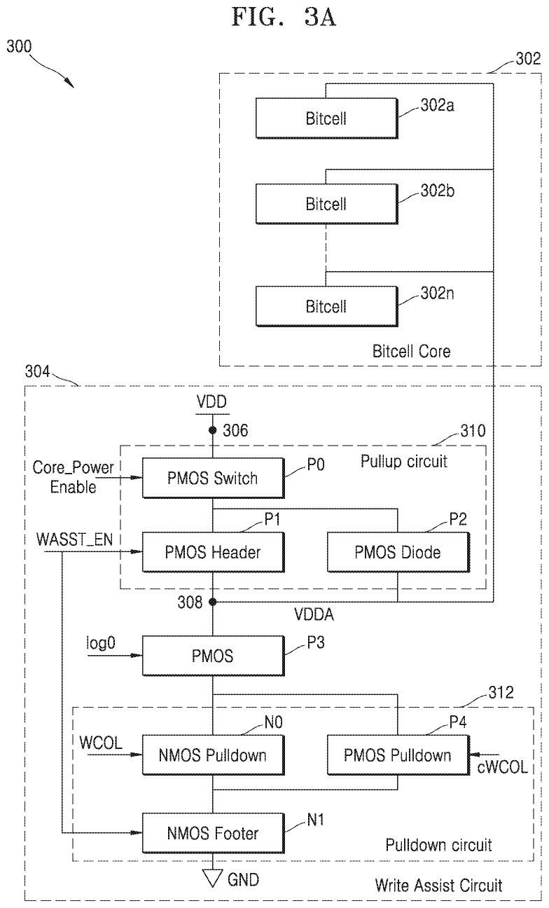

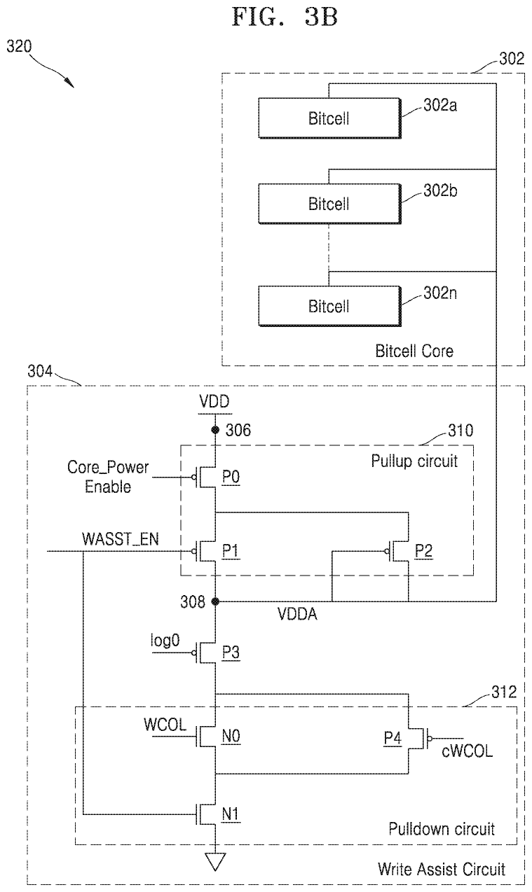

In an embodiment, the N0 may be controlled by a write column select signal (WCOL), the P4 may be controlled by a complementary WCOL (cWCOL), and the N1 may be controlled by one of the WASST_EN and the cWASST_EN. In an alternate embodiment, the N0 may be controlled by the WASST_EN, the P4 may be controlled by the cWASST_EN, and the N1 may be controlled by one of the write column select signal (WCOL) and the cWCOL. Different configurations of the write assist circuit 204 are explained in conjunction with FIGS. 3A-6B in the forthcoming paragraphs.

FIG. 3A illustrates a schematic architecture 300 of a write assist circuit 304 for generating the bitcell power supply voltage VDDA in the SRAM, according to a second embodiment of the present disclosure. In one embodiment, the generated VDDA may be supplied to a bitcell core 302. Particularly, the generated VDDA may be supplied to a plurality of bitcells 302a, 302b, . . . 302n in the bitcell core 302 ensuring a reliable write operation. In one embodiment, the bitcell 302a, 302b, . . . , 302n may refer to smallest unit of storage in the SRAM that holds a single bit of data.

In one embodiment, the write assist circuit 304 may include a pull-up circuit 310. The pull-up circuit 310 may include a PMOS switch P0, a PMOS header P1, and a diode (P2).

In an embodiment, the P0 may be coupled to a core power supply voltage node 306. In one embodiment, the node 306 may be connected to the VDD. In one embodiment, the P0 may be controlled by the core power enable (Core_Power Enable) signal. In one embodiment, the Core_Power Enable signal may refer to a control signal used to manage power supply to the bitcell core 302 in different modes of operation (such as a normal mode, a retention mode, and a power-down mode).

In one embodiment, the P1 may be coupled between the P0 and a bitcell power supply node 308. In one embodiment, the P1 may be controlled by a write assist enable signal (WASST_EN). In one embodiment, the WASST_EN signal may refer to a control signal used in the SRAM to enable or disable the write assist circuit 304 during the write operation. In one embodiment, the P1 may be configured to prevent a short supply path between the VDD and a ground (GND) during the pull-down operation.

In one embodiment, the diode may be coupled in a parallel fashion with the P1. In one embodiment, the diode may be configured to prevent an excessive pull-down of the bitcell power supply voltage VDDA which may cause a data corruption. Particularly, the diode may be configured to prevent the excessive pull-down of the bitcell power supply voltage VDDA in order to maintain a data retention voltage in the bitcells 302a, 302b, . . . 302n. In a non-limiting embodiment, the diode may be a PMOS diode P2 coupled in a parallel fashion with the P1 between the P0 and the node 308. In one embodiment, the P2 may be controlled by the bitcell power supply voltage VDDA.

In one embodiment, the write assist circuit 304 may include a pull-down circuit 310 configured to pull down the bitcell power supply voltage VDDA during the write operation. In one embodiment, the pull-down circuit 310 may include an NMOS pull-down transistor N0, a PMOS pull-down transistor P4 coupled in a parallel fashion with the NMOS pull-down transistor N0, and an NMOS footer N1 coupled between the N0 and the GND. In one embodiment, the N0 is controlled by a write column select signal (WCOL), the P4 is controlled by a complementary WCOL (cWCOL), and the N1 is controlled by the WASST_EN. In one embodiment, the WCOL signal may refer to a control signal used in the SRAM to select a column from among a plurality of columns (or bits) within a memory array during the write operation. In one embodiment, a pulse width of the WASST_EN signal may be based on a plurality of external pins. In one embodiment, a magnitude of pull-down of the bitcell power supply voltage VDDA may be based on the pulse width of the WASST_EN signal. In one embodiment, the P4 may enable a uniform pull-down of the bitcell power supply voltage VDDA across a plurality of process corners of the SRAM. In one embodiment, the plurality of process corners may include a fast NMOS-fast PMOS (FF) process corner, a slow NMOS-fast PMOS (SF) process corner, a fast NMOS-slow PMOS (FS) process corner, and a slow NMOS-slow PMOS (SS) process corner. In one embodiment, the P4 coupled in a parallel fashion with the NMOS pull-down transistor may enable an optimized pull-down of the bitcell power supply voltage VDDA for the SF process corner.

In one embodiment, the write assist circuit 304 may include a PMOS transistor P3 coupled between the P1 through the node 308 and the pull-down circuit 310. In one embodiment, the P3 is controlled by the logical low voltage (log 0) and provides a pull-down path for the bitcell power supply voltage VDDA. Additionally, the P3 prevents the excessive pull-down of the bitcell power supply voltage VDDA below the data retention voltage.

An operation of the write assist circuit 304 during different operating modes is explained in detail in the forthcoming paragraphs.

During a normal mode when no write operation is happening, the Core_Power Enable signal and the WASST_EN signal may remain low (i.e., logic ‘0’) thereby turning the P0 and P1 ON respectively. The low WASST_EN signal also turns off the N1. Similarly, when no write operation is happening, the WCOL signal may remain low (i.e., logic ‘0’), making the cWOL signal high (i.e., logic ‘1’). The low WCOL signal and the high cWCOL signal turn the N0 and P4 OFF respectively. Since there is no contention, the bitcell power supply voltage VDDA becomes equal to the VDD. Accordingly, no lowering of the bitcell power supply voltage VDDA is applied when there is no write operation. Further, for the P2, a gate-source voltage (V_{GS}) and a drain-source voltage (V_{DS}) may be 0, thus, the P2 may be in a cutoff mode. Additionally, for the P3, the V_{DS} may be 0, thereby turning the P3 OFF.

In one embodiment, during the write operation, particularly, when writing to a particular column from among the plurality of columns is enabled, the Core_Power Enable signal may be low (i.e., logic ‘0’), thereby turning the P0 ON. Further, the WASST_EN signal may be high (i.e., logic ‘1’), thereby turning the P1 OFF. Additionally, the WCOL signal may also be high (i.e., logic ‘1’) making the cWCOL signal low (i.e., logic ‘0’), and thereby turning the N0 and the P4 ON respectively. Since, the WASST_EN is high, the N1 may be turned ON. Since the pull-down circuit 312 is enabled, the bitcell power supply voltage VDDA may be lowered from the VDD. In one embodiment, the P2 and the P3 may assist in avoiding the lowering of the bitcell power supply voltage VDDA beyond a bitcell retention voltage. In one embodiment, the bitcell retention voltage may refer to a minimum voltage required to maintain a stored data in the bitcell 302a, 302b, . . . , 302n of the SRAM without the data corruption or loss.

In one embodiment, during the write operation when the writing is not enabled for any of the plurality of columns, the Core_Power Enable signal may be low (i.e., logic ‘0’), thereby turning the P0 ON. Further, the WASST_EN signal may be high (i.e., logic ‘1’), thereby turning the P1 OFF and the N1 ON. However, the WCOL signal may be low (i.e., logic ‘0’) making the cWCOL signal high (i.e., logic ‘1’), and which may turn the N0 and the P4 OFF respectively. In such a case, the bitcell power supply voltage VDDA may be maintained at the bitcell retention voltage through the P0 and the P2.

In one embodiment, during the write operation when a bit write mask may be applied for the bitcells 302a, 302b, . . . , 302n, the Core_Power Enable signal may be low (i.e., logic ‘0’), thereby turning the P0 ON. Further, the WASST_EN signal may also be low (i.e., logic ‘0’), thereby turning the P1 ON and the N1 OFF. In such a case, the bitcell power supply voltage VDDA may be equal to the VDD.

Further, during a power down mode, the Core_Power Enable signal may be high (i.e., logic ‘1’), thereby turning the P0 OFF. Since the P0 is turned off (i.e., bitcell power supply being switched OFF), the bitcell power supply voltage VDDA becomes 0. In one embodiment, during the power down mode, the WASST_EN signal, the WCOL signal, and the cWCOL signal may be in undefined states.

FIG. 3B illustrates a circuit diagram 320 of the write assist circuit 304 of FIG. 3A, according to the second embodiment of the present disclosure. The components of the circuit diagram 320 are same as that of the architecture 300 of FIG. 3A. Accordingly, description thereof has been omitted for the sake of brevity.

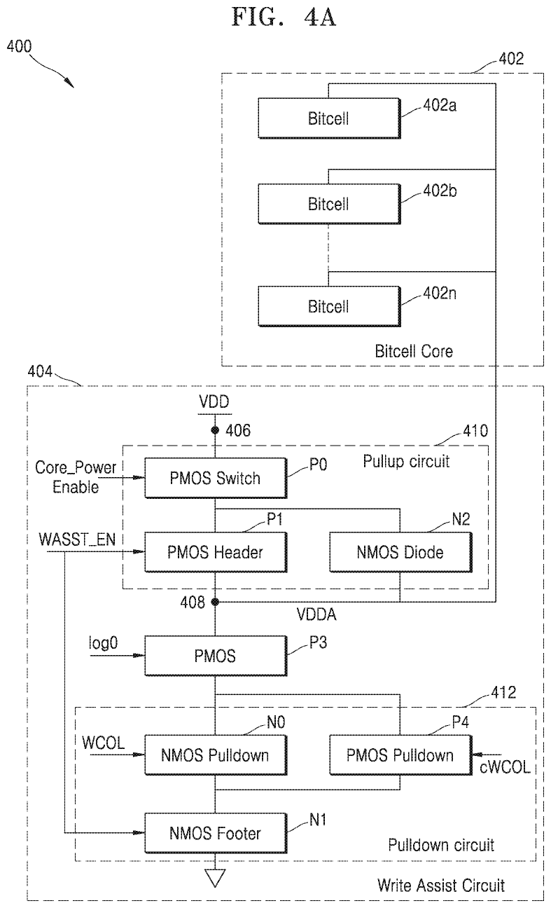

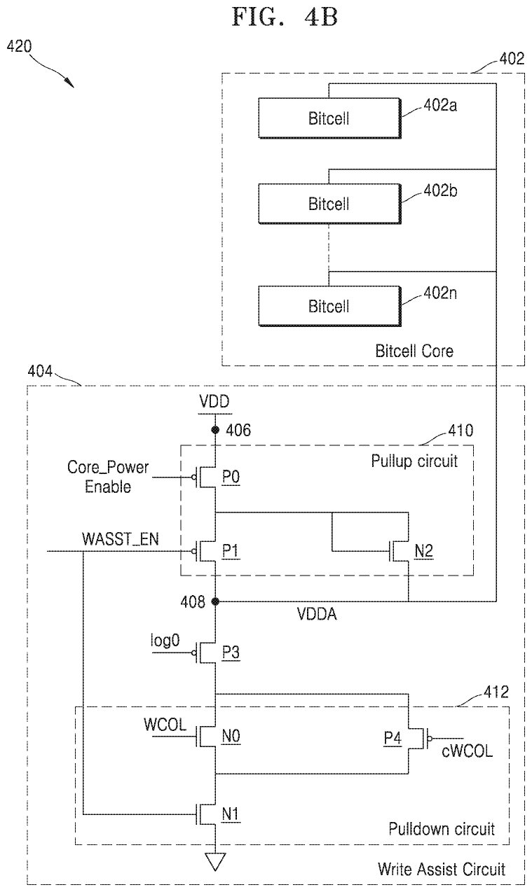

FIG. 4A illustrates a schematic architecture 400 of a write assist circuit 404 for generating the bitcell power supply voltage VDDA in the SRAM, according to a third embodiment of the present disclosure. In one embodiment, the write assist circuit 404 may include the diode. In a non-limiting embodiment, the diode may be an NMOS diode N2. The components P0-P1, P3-P4, and N0-N1, voltage nodes 406 and 408, a pull-down circuit 410 of the write assist circuit 404 may be same as that of the write assist circuit 304 of FIG. 3A, and a bitcell core 402 may correspond to the bitcell core 302. Accordingly, the description thereof has been omitted for the sake of brevity.

FIG. 4B illustrates a circuit diagram 420 of the write assist circuit 404 of FIG. 4A, according to the third embodiment of the present disclosure. The components of the circuit diagram 420 are same as that of the architecture 400 of FIG. 4A. Accordingly, description thereof has been omitted for the sake of brevity.

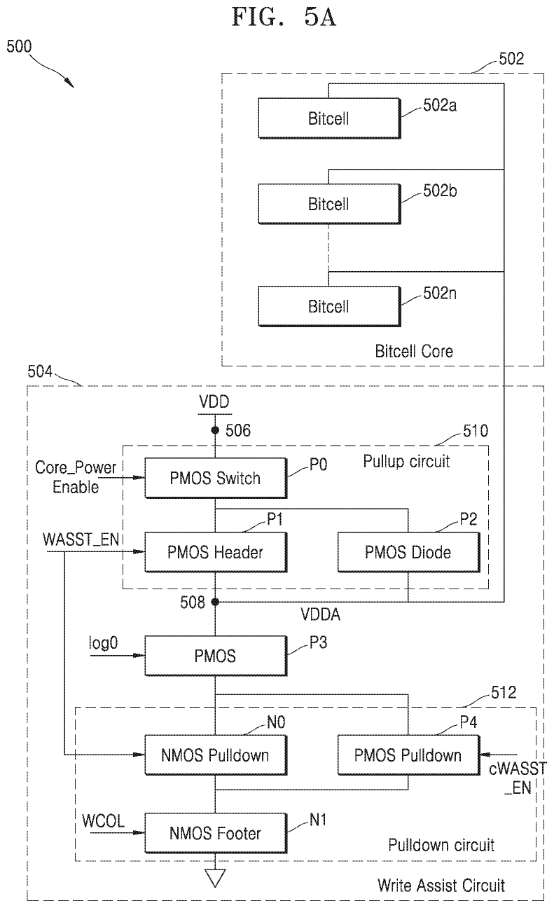

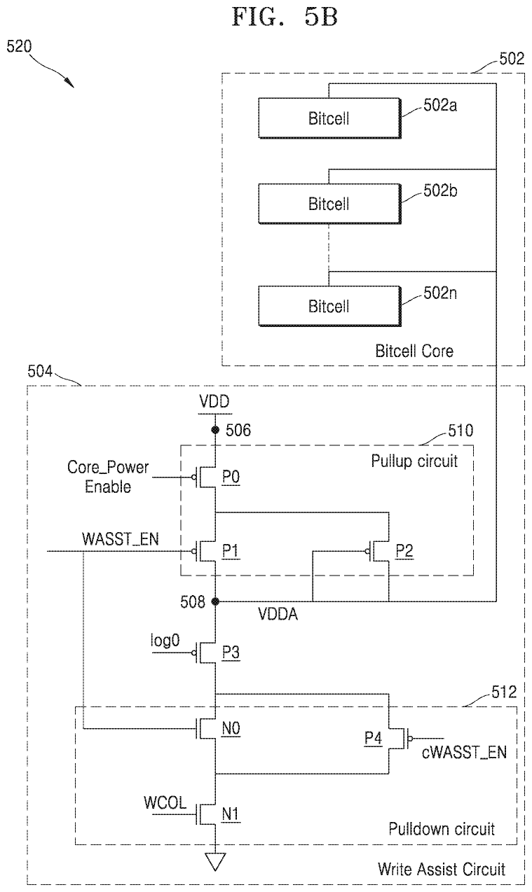

FIG. 5A illustrates a schematic architecture 500 of a write assist circuit 504 for generating the bitcell power supply voltage VDDA in the SRAM, according to a fourth embodiment of the present disclosure. The components P0-P4 and N0-N1, and voltage nodes 506 and 508 of the write assist circuit 504 may be same as that of the write assist circuit 304 of FIG. 3A, and a bitcell core 502 may correspond to the bitcell core 302. Accordingly, the description thereof has been omitted for the sake of brevity.

In a non-limiting embodiment, in a pull-down circuit 512 of the write assist circuit 504, the N0 may be controlled by the WASST_EN signal, the P4 may be controlled by a complementary WASST_EN (cWASST_EN) signal, and the N1 may be controlled by the WCOL signal.

FIG. 5B illustrates a circuit diagram 520 of the write assist circuit 504 of FIG. 5A, according to the fourth embodiment of the present disclosure. The components of the circuit diagram 520 are same as that of the architecture 500 of FIG. 5A. Accordingly, the description thereof has been omitted for the sake of brevity.

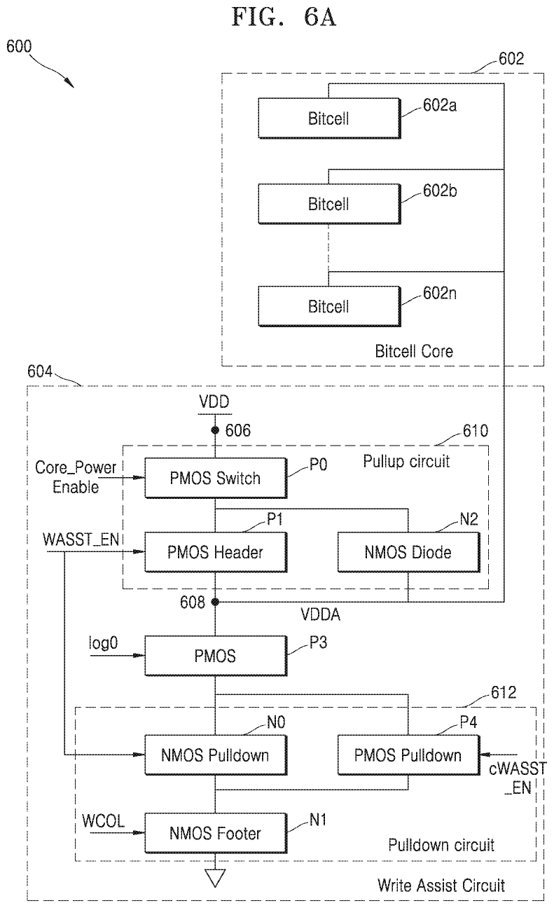

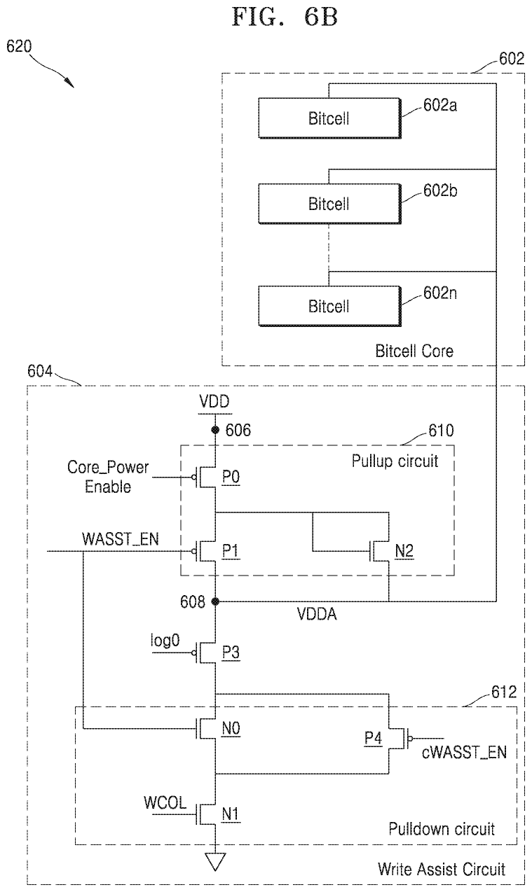

FIG. 6A illustrates a schematic architecture 600 of a write assist circuit 604 for generating the bitcell power supply voltage VDDA in the SRAM, according to a fifth embodiment of the present disclosure. In one embodiment, the write assist circuit 604 may include the diode. In a non-limiting embodiment, the diode may be the NMOS diode N2. The components P0-P1, P3-P4, and N0-N1, voltage nodes 606 and 608, a pull-down circuit 612 of the write assist circuit 604 may be same as that of the write assist circuit 504 of FIG. 5A, and a bitcell core 602 may correspond to the bitcell core 502. Accordingly, the description thereof has been omitted for the sake of brevity.

FIG. 6B illustrates a circuit diagram 620 of the write assist circuit 604 of FIG. 6A, according to the fifth embodiment of the present disclosure. The components of the circuit diagram 620 are same as that of the architecture 600 of FIG. 6A. Accordingly, description thereof has been omitted for the sake of brevity.

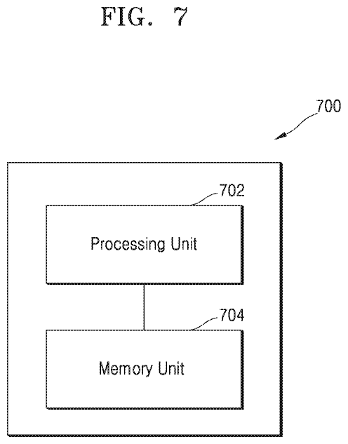

FIG. 7 illustrates a computing system 700, in accordance with one or more embodiments of the present disclosure. The write assist circuit 204, 304, 404, 504, or 604 may be implemented in the computing system 700, according to one or more example embodiments of the present disclosure. The computing system 700 is, or is incorporated into but not limited to, a smartphone, a personal digital assistant, a personal computer, smartwatches, fitness trackers, a palmtop computer, a laptop computer, a desktop computer, a communications device, a wireless telephone, a land-line telephone, a web appliance, a network router, switch or bridge, or any other machine capable of executing a set of instructions (sequential or otherwise) that specify actions to be taken by that machine or any other type of electronic system. Further, while a single computing system 700 is illustrated, the term “system” shall also be taken to include any collection of systems or sub-systems that individually or jointly execute a set, or multiple sets, of instructions to perform one or more computer functions.

In one embodiment, the computing system 700 comprises a system-on-chip (SoC) which includes control logic such as a processing unit 702 (Central Processing Unit), and a memory unit 704 (e.g., random access memory (RAM).

The processing unit 702 can be, for example, a CISC-type (Complex Instruction Set Computer) CPU, RISC-type CPU (Reduced Instruction Set Computer), a digital signal processor (DSP), or a graphics processing unit (GPU). The processing unit 702 may be a component in a variety of systems. For example, the processing unit 702 may be part of a standard personal computer or a workstation. The processing unit 702 may be one or more general processors, digital signal processors, application-specific integrated circuits, field-programmable gate arrays, servers, networks, digital circuits, analog circuits, combinations thereof, or other now known or later developed devices for analyzing and processing data. The processing unit 702 may implement a software program, such as code generated manually (i.e., programmed).

The memory unit 704 (which can be memory such as RAM, flash memory, or disk storage) stores one or more software applications (e.g., embedded applications) that, when executed by the processing unit 702, perform any suitable function associated with the computing system 700. The memory unit 704 may include but is not limited to computer-readable storage media such as various types of volatile and non-volatile storage media, including but not limited to random access memory, read-only memory, programmable read-only memory, electrically programmable read-only memory, electrically erasable read-only memory, flash memory, magnetic tape or disk, optical media and the like. In one embodiment, the memory unit 704 may include the SRAM, where the write assist circuit 204, 304, 404, 504 or 604 may be implemented.

In the foregoing discussion, the term “connected” means at least either a direct electrical connection between the devices connected or an indirect connection through one or more passive intermediary devices. The term “circuit” means at least either a single component or a multiplicity of passive components, that are connected together to provide a desired function. Also, the terms “coupled to” or “couples with” (and the like) are intended to describe either an indirect or direct electrical connection. Thus, as an example, if an electronic device is coupled to another electronic device, that connection can be through a direct electrical connection, or through an indirect electrical connection via other devices and connections.

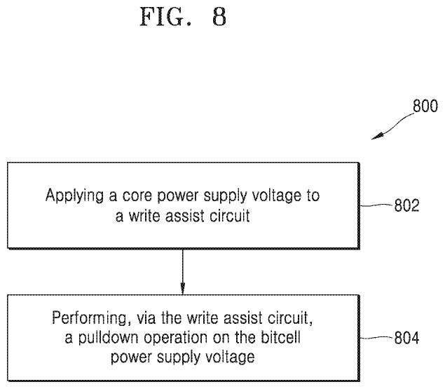

FIG. 8 illustrates a flow chart of a method 800 for generating the bitcell power supply voltage VDDA in the SRAM, in accordance with one or more embodiments of the present disclosure.

At operation 802, the method 800 may include applying the VDD to the write assist circuit 204, 304, 404, 504, or 604.

At operation 804, the method 800 may include performing, via the write assist circuit 204, 304, 404, 504, or 604, the pull-down operation on the bitcell power supply voltage VDDA.

Conventional solutions provide the write assist circuit for lowering the bitcell power supply voltage VDDA, however, said solutions are based on NMOS-assisted pull-down which results in non-uniform lowering of the bitcell power supply voltage VDDA across different process corners. Particularly, the NMOS-assisted pull-down provided worst assist level for the SF corner, where the write operation is also weak. On the other hand, the present disclosure employs the PMOS pull-down transistor in parallel with the NMOS pull-down transistor, which allows for uniform dip in the bitcell power supply voltage VDDA across all the process corners, thereby improving the write operation performance in the SRAM.

The present disclosure provides various advantages. For instance, the present disclosure provides an improved assist level in the SF process corner and reduces a minimum operating voltage of the SRAM as compared to the related art techniques. The present disclosure enables a uniform dip in the bitcell power supply voltage VDDA across all the process corners, thereby improving the performance of the SRAM write operation. The present disclosure further improves speed and dynamic power consumption of macros of the SRAM. Additionally, the present disclosure ensures a reliable write operation in the SRAM, particularly at low voltages.

Unless otherwise defined, all technical and scientific terms used herein have the same meaning as commonly understood by one of ordinary skilled in the art. The system, methods, and examples provided herein are illustrative only and not intended to be limiting.

Benefits, other advantages, and solutions to problems have been described above with regard to specific embodiments. However, the benefits, advantages, solutions to problems, and any component(s) that may cause any benefit, advantage, or solution to occur or become more pronounced are not to be construed as a critical, required, or essential feature or component of any or all the claims.

While specific language has been used to describe the present subject matter, any limitations arising on account thereto, are not intended. As would be apparent to a person in the art, various working modifications may be made to the method in order to implement embodiments of the present disclosure. The drawings and the foregoing description give examples of embodiments. Those skilled in the art will appreciate that one or more of the described elements may well be combined into a single functional element. Alternatively, certain elements may be split into multiple functional elements. Elements from one embodiment may be added to another embodiment.

What is claimed is:

1. A write assist circuit for generating a bitcell power supply voltage in a static random access memory (SRAM), wherein the write assist circuit is configured to perform a pull-down operation on the bitcell power supply voltage, the write assist circuit comprising:
a pull-up circuit coupled to a bitcell power supply node, wherein the pull-up circuit is configured to be controlled by a core power enable signal and a write assist enable signal, and to prevent a short supply path between a core power supply voltage and a ground during the pull-down operation;
a pass gate coupled to the pull-up circuit through the bitcell power supply node, wherein the pass gate is configured to be controlled by one of a logical low voltage and a logical high voltage, and to provide a pull-down path for the bitcell power supply voltage; and
a pull-down circuit configured to pull down the bitcell power supply voltage during a write operation, the pull-down circuit comprising:
an n-type metal-oxide-semiconductor (NMOS) pull-down transistor,
a p-type metal-oxide-semiconductor (PMOS) pull-down transistor coupled in parallel with the NMOS pull-down transistor, and
a footer coupled between the NMOS pull-down transistor and the ground.

2. The write assist circuit of claim 1, wherein the pull-up circuit comprises:
a switch coupled to a core power supply voltage node, wherein the switch is configured to be controlled by the core power enable signal;
a header coupled between the switch and the pass gate, wherein the header is configured to be controlled by one of the write assist enable signal and a complementary write assist enable signal, and to prevent the short supply path between the core power supply voltage and the ground during the pull-down operation; and
a diode coupled in parallel with the header, wherein the diode is configured to prevent an excessive pull-down of the bitcell power supply voltage.

3. The write assist circuit of claim 2, wherein the switch is one of a PMOS switch and an NMOS switch,
wherein the header is one of a PMOS header and an NMOS header, and
wherein the diode is one of a PMOS diode and an NMOS diode.

4. The write assist circuit of claim 1, wherein the NMOS pull-down transistor is configured to be controlled by a write column select signal, the PMOS pull-down transistor is configured to be controlled by a complementary write column select signal, and the footer is configured to be controlled by one of the write assist enable signal and the complementary write assist enable signal.

5. The write assist circuit of claim 4, wherein the NMOS pull-down transistor is configured to be controlled by the write assist enable signal, the PMOS pull-down transistor is configured to be controlled by the complementary write assist enable signal, and the footer is configured to be controlled by one of the write column select signal and the complementary write column select signal.

6. The write assist circuit of claim 1, wherein the pass gate is one of a PMOS gate and an NMOS gate, and
wherein the footer is one of a PMOS footer and an NMOS footer.

7. The write assist circuit of claim 1, wherein a pulse width of the write assist enable signal is based on a plurality of external input pins.

8. The write assist circuit of claim 7, wherein a magnitude of pull-down of the bitcell power supply voltage is based on the pulse width of the write assist enable signal.

9. The write assist circuit of claim 1, wherein the PMOS pull-down transistor is configured to enable a uniform pull-down of the bitcell power supply voltage across a plurality of process corners of the SRAM.

10. The write assist circuit of claim 9, wherein the plurality of process corners comprises a fast NMOS-fast PMOS (FF) process corner, a slow NMOS-fast PMOS (SF) process corner, a fast NMOS-slow PMOS (FS) process corner, and a slow NMOS-slow PMOS (SS) process corner.

11. The write assist circuit of claim 10, wherein the PMOS pull-down transistor coupled in parallel with the NMOS pull-down transistor is configured to enable an optimized pull-down of the bitcell power supply voltage for the SF process corner.

12. A method of controlling a write assist circuit for generating a bitcell power supply voltage in a static random access memory (SRAM), the write assist circuit including a pull-up circuit coupled to a bitcell power supply node, and controlled by a core power enable signal and a write assist enable signal, a pass gate coupled to the pull-up circuit through the bitcell power supply node, and controlled by one of a logical low voltage and a logical high voltage and a pull-down circuit coupled between the pass gate and a ground and configured to pull down the bitcell power supply voltage during a write operation, the pull-down circuit including an n-type metal-oxide-semiconductor (NMOS) pull-down transistor, and a p-type metal-oxide-semiconductor (PMOS) pull-down transistor coupled in parallel with the NMOS pull-down transistor, the method comprising:
applying a core power supply voltage to the write assist circuit; and
performing, via the write assist circuit, a pull-down operation on the bitcell power supply voltage.

13. The method of claim 12, wherein the pull-up circuit comprises:
a switch coupled to a core power supply voltage node, wherein the switch is controlled by the core power enable signal;
a header coupled between the switch and the pass gate, wherein the header is controlled by one of the write assist enable signal and a complementary write assist enable signal, and is configured to prevent a short supply path between the core power supply voltage and the ground during the pull-down operation; and
a diode coupled in parallel with the header, wherein the diode is configured to prevent an excessive pull-down of the bitcell power supply voltage.

14. The method of claim 12, wherein the NMOS pull-down transistor is controlled by a write column select signal, the PMOS pull-down transistor is controlled by a complementary write column select signal.

15. The method of claim 12, wherein the NMOS pull-down transistor is controlled by the write assist enable signal, the PMOS pull-down transistor is controlled by the complementary write assist enable signal.

16. The method of claim 12, wherein a magnitude of pull-down of the bitcell power supply voltage is based on a pulse width of the write assist enable signal.

17. A write assist circuit for generating a bitcell power supply voltage provided to bitcells in a static random access memory (SRAM), the write assist circuit comprising:
a pull-up circuit coupled between a power supply node to which a core power supply voltage is applied and a output node from which the bitcell power supply voltage is output;
a pass transistor coupled to the pull-up circuit through the output node; and
a pull-down circuit coupled between the pass transistor and ground and configured to pull down the bitcell power supply voltage, the pull-down circuit comprising:
a first-type pull-down transistor configured to be turned on based on a first control signal; and
a second-type pull-down transistor coupled in parallel with the first-type pull-down transistor and configured to be turned on based on a complementary signal of the first control signal, the second-type pull-down transistor being different from the first-type pull-down transistor.

18. The write assist circuit of claim 17, wherein the pull-up circuit comprises:
a switch coupled to the power supply node, wherein the switch is controlled by a core power enable signal;
a header coupled between the switch and the pass transistor, wherein the header is controlled by one of a write assist enable signal and a complementary write assist enable signal, and is configured to prevent a short supply path between the core power supply voltage and the ground during a pull-down operation; and
a diode coupled in parallel with the header, wherein the diode is configured to prevent an excessive pull-down of the bitcell power supply voltage.

19. The write assist circuit of claim 17, wherein the pass gate is configured to provide a pull-down path for the bitcell power supply voltage.

20. The write assist circuit of claim 17, wherein the the pull-down circuit further comprises a footer transistor coupled between the first-type pull-down transistor and the ground.
